(19) United States
(12) Patent Application Publication
(10) Pub. No.: US 2007/0228435 A1
(43) Pub. Date: Oct. 4, 2007

(54) Semiconductor device and fabrication thereof

(75) Inventors: Jar-Ming Ho, Taipei City (TW); Shian-Jyh Lin, Taipei County (TW); Chin-Tien Yang, Hsinchu City (TW); Chien-Li Cheng, Hsinchu City (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/476,266

(22) Filed: Jun. 28, 2006

(30) Foreign Application Priority Data
Apr. 3, 2006 (TW) TW95111776

(51) Int. Cl. H01L 29/94

(52) U.S. Cl. 257/296

(57) ABSTRACT

A method for forming a semiconductor device is disclosed, in which a substrate comprising a recessed gate is provided, and a protrusion of the recessed gate protrudes a surface of the substrate. A spacer is formed on a sidewall of the protrusion of the recessed gate. A conductive structure is formed overlying the recessed gate, wherein the conductive structure is narrower than the recessed gate to expose a portion of the recessed gate. An etching process is utilized to recess a exposed portion of the recessed gate, and form a recess portion between the recessed gate and the spacer. A conductive line spacer is formed on a sidewall of the conductive line structure, wherein the conductive line spacer fills the recessed portion.

### BACKGROUND OF THE INVENTION

1. Field of the Invention

The invention relates to a semiconductor device and fabrication thereof, and more particularly to a memory device and fabrication thereof.

2. Description of the Related Art

In the rapidly evolving integrated circuit industry there is a development tendency toward high performance, miniaturization, and high operating speed. Additionally, dynamic random access memory (DRAM) fabrication methods have developed rapidly.

Typically, current dynamic random access memory DRAM cells include a transistor and a capacitor. Since the capacity of current DRAM has reached 256 MB and up to 512 MB, the size of memory cells and transistors has narrowed to meet demands for high integration, higher memory capacity and higher operating speeds. In conventional planar transistor technology, however, more useable surface area on a chip is required, and it is difficult to meet the previously mentioned demands. Accordingly, recessed gate and channel technology has been applied to DRAM fabrication with the goal of reducing the area occupied by the transistor and the capacitor on the semiconductor substrate. Conventional planar transistor technology, however, requires a large amount of surface area on the chip, and cannot accomplish the demand for high integration. Conversely, the disadvantages of the conventional semiconductor memory cell can be improved by applying recessed vertical gate transistor RVERT technology to DRAM fabrication. RVERT technology is positioned to become a major semiconductor memory cell fabrication method.

FIG. 1 is a top view of conventional vertical gate transistor. Referring to FIG. 1, a distance between a recessed gate 103 and a deep trench capacitor 105 must be controlled precisely due to requirement for controlling out diffusion distance D. The overlay control of forming recessed gate 103 in a conventional lithography process, however, is very tight when process generation is 60 nm or smaller. Consequently, applicants have also disclosed a method for forming a vertical transistor in U.S. patent application Ser. No. 11/145,725, comprising a patterned pad layer used as a rounded spacer. A substrate is etched using the rounded spacer and a trench top insulating layer on a top portion of a trench capacitor as a mask to form a trench of a recess gate by self-alignment.

### BRIEF SUMMARY OF THE INVENTION

A detailed description is given in the following embodiments with reference to the accompanying drawings. These and other problems are generally solved or circumvented, and technical advantages are generally achieved, by preferred illustrative embodiments of the present invention, which provide a semiconductor device.

A method for forming a semiconductor device is disclosed, in which a substrate comprising a recessed gate is provided, and a protrusion of the recessed gate protrudes a surface of the substrate. A spacer is formed on a sidewall of the protrusion of the recessed gate. A conductive structure is formed overlying the recessed gate, wherein the conductive structure is narrower than the recessed gate to expose a portion of the recessed gate. An etching process is utilized to recess an exposed portion of the recessed gate, and form a recess portion between the recessed gate and the spacer. A conductive line spacer is formed on a sidewall of the conductive line structure, wherein the conductive line spacer fills the recessed portion.

A semiconductor device is also disclosed, comprising a recessed gate disposed in a substrate, wherein a protrusion of the recessed gate protrudes a surface of the substrate. A spacer is disposed overlying a sidewall of the protrusion of the recessed gate. A word line is disposed overlying the recessed gate, wherein the word line is narrower than the recessed gate. A word line spacer is disposed on a sidewall of the word line and extends downward into the recessed gate.

### BRIEF DESCRIPTION OF THE DRAWINGS

The invention can be more fully understood by reading the subsequent detailed description and examples with references made to the accompanying drawings, wherein:

FIG. 1 is a top view of conventional vertical gate transistor.

FIG. 2 illustrates a top view of a memory device of an embodiment of the invention.

FIG. 3A-FIG. 3J illustrate intermediate cross sections of a memory device of an embodiment of the invention.

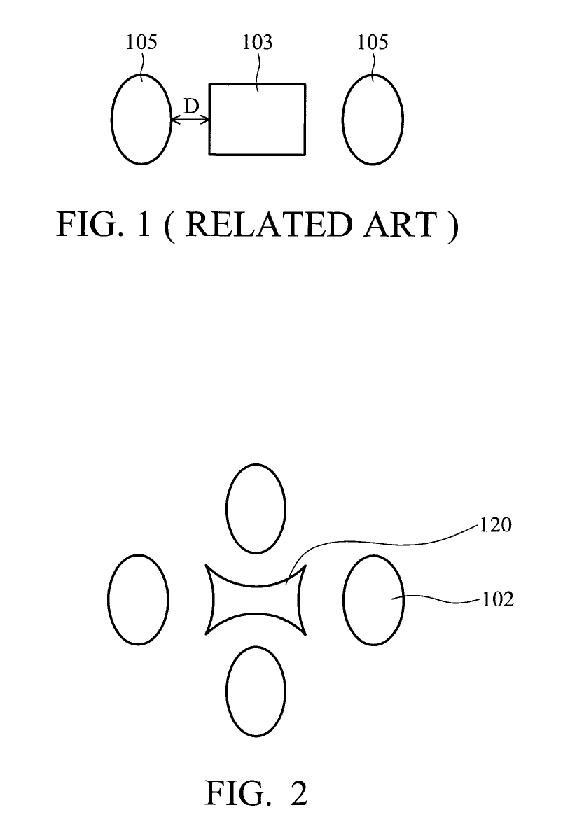

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims. Embodiments of the invention, which provides a semiconductor device, will be described in greater detail by referring to the drawings that accompany the invention. It is noted that in the accompanying drawings, like and/or corresponding elements are referred to by like reference numerals.

FIG. 2 illustrates a top view of a memory device of an embodiment of the invention. In the memory device, a recess gate 120 is defined by a plurality of deep trench capacitor 102 surrounding the recess gate 120 and spacers (not shown) on sidewalls of the deep trench capacitors 102.

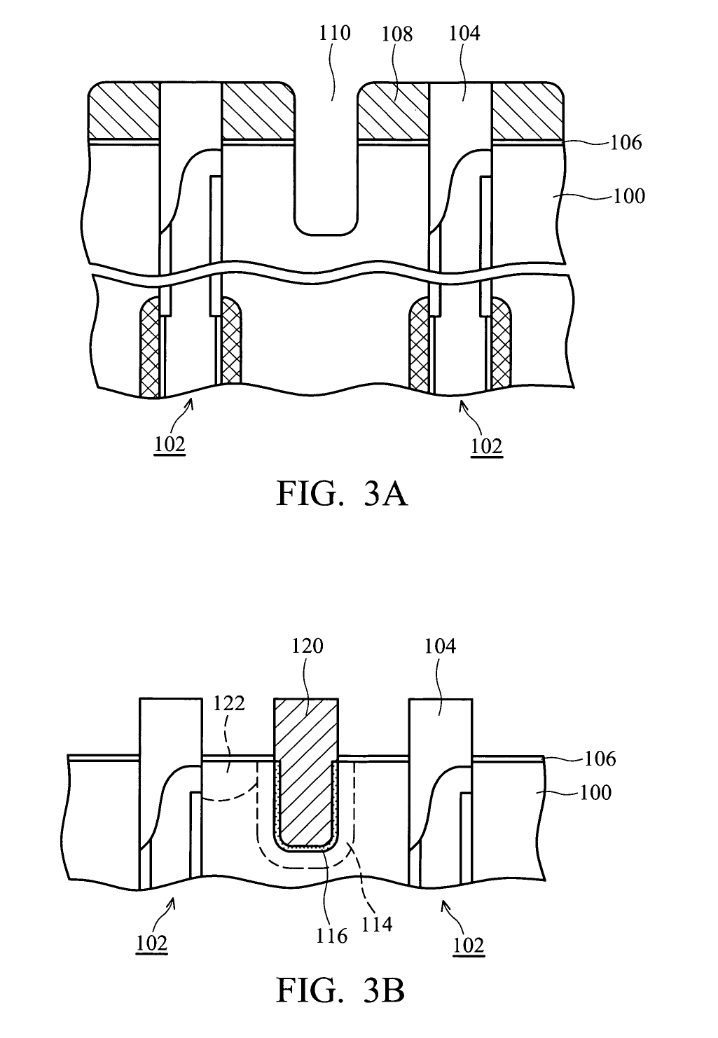

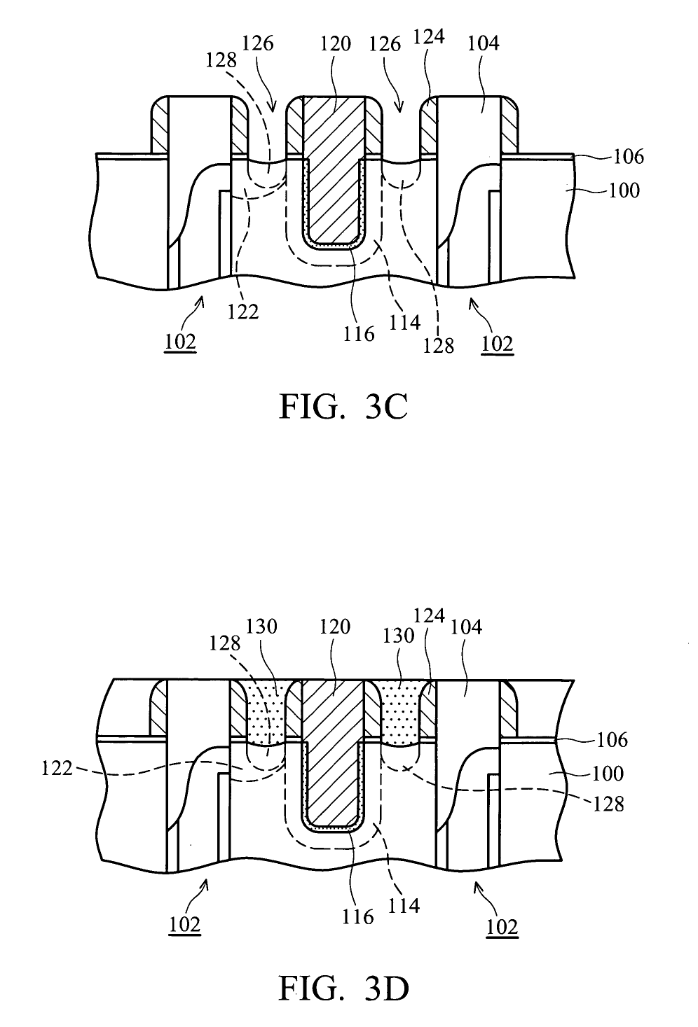

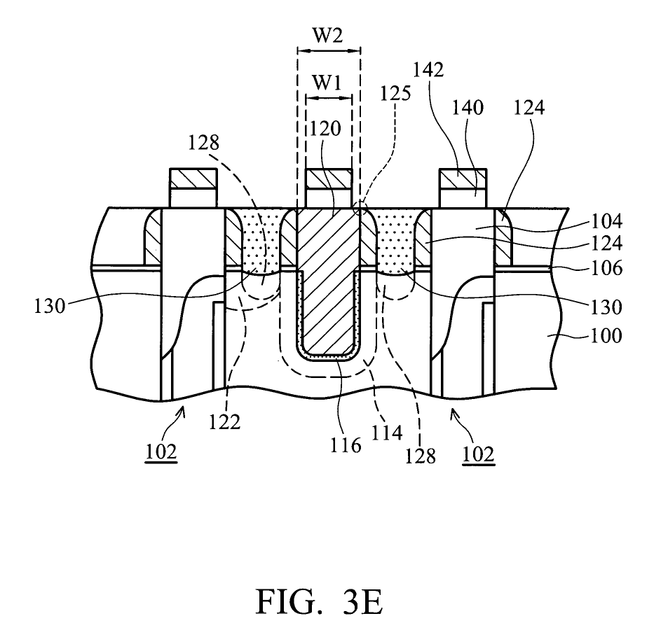

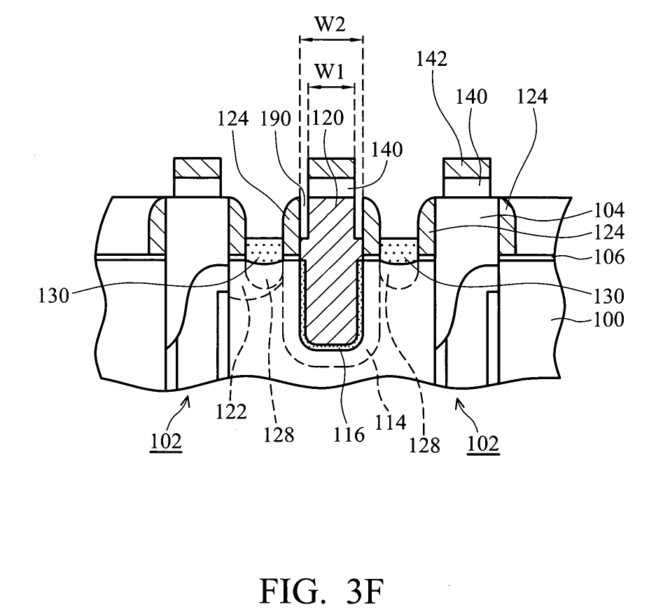

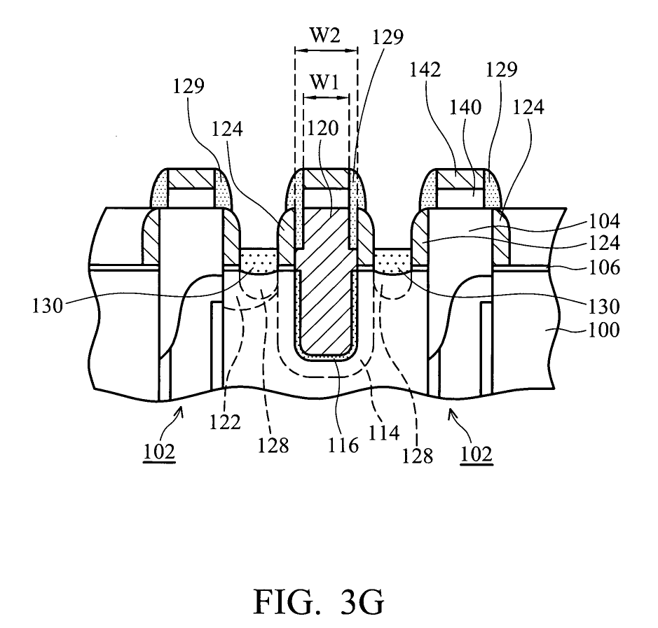

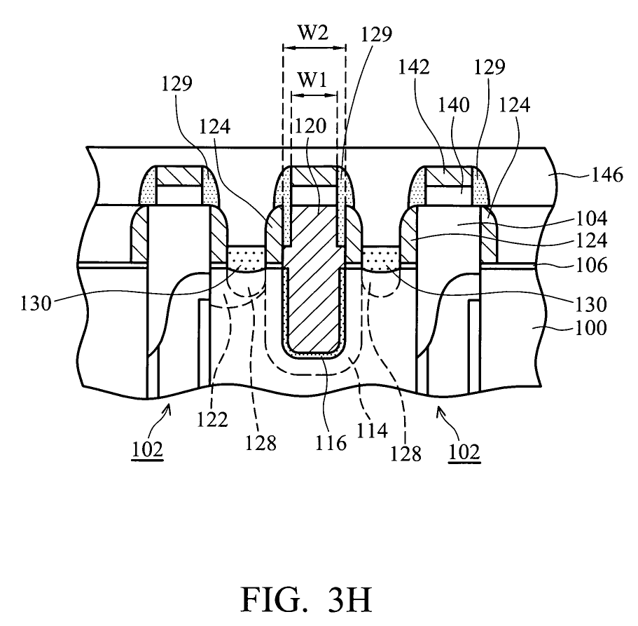

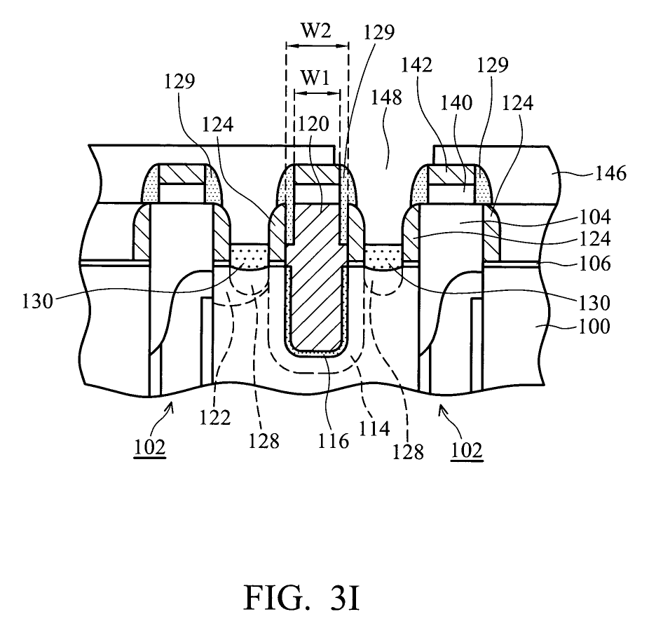

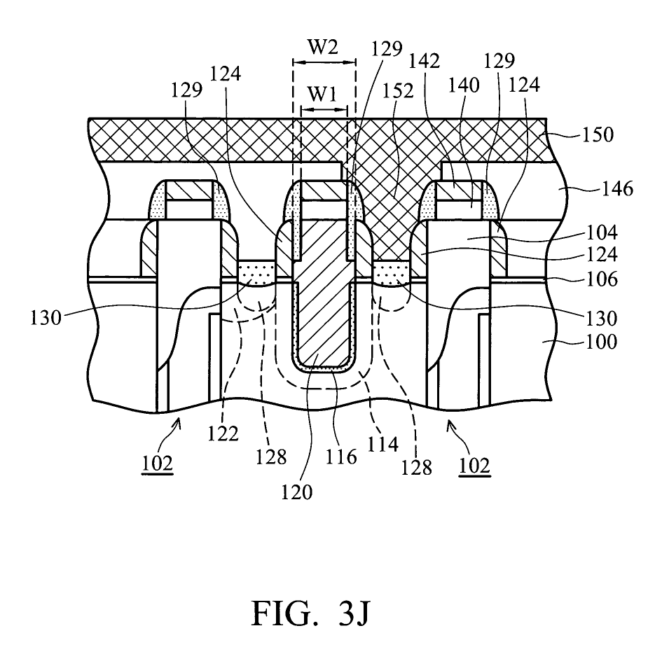

FIG. 3A-FIG. 3J illustrate intermediate cross sections of a memory device of an embodiment of the invention. Referring to FIG. 3A, a substrate 100 is provided. The substrate 100 comprises deep trench capacitors 102 therein, and the upper portions 104 of the deep trench capacitors 102 are above the surface of the substrate 100. A pad layer 106 and a dielectric cap layer 108, such as nitride (SiN) are formed on the sidewalls of the upper portions 104 of the deep trench capacitors 102. The profile of the dielectric cap layer 108 has a concave area which is substantially at the middle of two upper portions 104 of the nearby deep trench capacitors. Thus, the substrate 100 can be etched by self-alignment using the dielectric cap layer 108 and the pad layer 106 as a mask to form a recessed trench 110 between the deep trench capacitors 102.

Referring to FIG. 3B, a portion of the substrate 100 adjacent to the recessed trench 110 is doped to form channel area 114 surrounding the recessed trench 110. A gate dielectric layer 116, preferably comprising silicon oxide, is then formed on sidewalls of the recessed trench 110. A conductive material, such as polysilicon, tungsten or tungsten silicide, is filled in the recessed trench 110 to form a recessed gate electrode 120. An out diffusion region 122 connecting the deep trench capacitors 102 and the channel area 114 is formed during the thermal process of forming the gate dielectric layer 116 and/or the other thermal process in subsequent processes.

The upper portions 104 of deep trench capacitors 102, the dielectric cap layer 108, and the upper surface of the recessed gate electrodes 118 are planarized. The dielectric cap layer 108 is then stripped by selective wet etching to reveal the upper portions 104 of deep trench capacitors 102 and the protrusions of the recessed gate 120. The planarizing method comprises a chemical mechanical polishing (CMP) process, a blanket etching back process or a recess etching process. Preferably, the upper surfaces of the protrusion of the recessed gate 120 are substantially at the same level as the upper portions 104 of the deep trench capacitors 102.

Referring to FIG. 3C, spacers 124 are formed on sidewalls of the upper portions 104 of the deep trench capacitors and the protrusion of the recess gate 120, such that space 126 between the spacers 124 are formed by self-alignment. The spacers 124 can be formed by deposition and dry etching back of a CVD silicon nitride film. Preferably, the spacers 124 enclose the upper portions 104 of the deep trench capacitors 102 and the protrusion of the recess gate 120, and the circular spaces 126 are exposed beyond coverage of the deep trench capacitors 102, the recessed gate 120 and the spacers 124. Thereafter, an ion implantation step is executed to form source/drain regions 128 on opposite sides of the recessed channel area 114 and under the spaces 126.

Referring to FIG. 3D, a layer of conductive material, preferably comprising doped poly or metal, is deposited to fill the spaces 126 between the spacers 124. The layer of conductive material, the spacers 124, the deep trench capacitors 102 and the recessed gate 120 are then planarized to form contact portions 130 in the spaces 126 between the spacers 124. Preferably, the contact portions 130 surround the upper portions 104 of the deep trench capacitors 102. The planarizing process can be a chemical mechanical polish (CMP) process, a blanket etching back process or a recess etching process.

Referring to FIG. 3E, a conductive material layer, for example comprising metal silicide such as WSix or metal such as tungsten, is blanketly deposited on the substrate 100. In a preferred embodiment of the invention, the conductive material layer is about 800 Å˜1500 Å thick. Next, a dielectric inaterial layer, such as silicon nitride preferably about 800 Å˜1500 Å thick, is blanketly deposited on the conductive material layer. Note that the dielectric material layer can be used as an etching stop layer of a self-aligned process in subsequent steps.

Next, the dielectric material layer and the conductive material layer are patterned by typical lithography and etching to form word lines 140 (also called conductive structure) and gate cap layers 142, wherein the word lines 140 passing through the deep trench capacitor 102 and the recessed gate 120. In a preferred embodiment of the invention, width W1 of each word line 140 is narrower than the width W2 of the recessed gate 120.

In a preferred embodiment of the invention, the width W2 of the recessed gate 120 is substantially 1.1˜1.3 times the critical dimension of the semiconductor device. Width W1 of the word line 140 is substantially 0.7˜0.9 times the critical dimension of the semiconductor device, and the width W2 of the word line 140 is substantially 0.6˜0.8 times width W1 of the recess gate 120.

Referring to FIG. 3E, since the spacers 124 are formed by deposition and etching back, top portions 125 of the spacers 124 are narrower than lower portions thereof, thus, affecting isolation. Accordingly, leakage current between conductive contact portions 130 between two adjacent spacers 124 and the recess gate 120 may occur, affecting performance of the semiconductor device.

Referring to FIG. 3F, in accordance with the described problem, an anisotropic etching, such as plasma etching, is preferably utilized using the gate cap layer 142, the top portions 104 of the deep trench capacitors 102 and the spacers 124 as a mask to recess the exposed recess gate 120 and the contact portions 130 between two adjacent spacers 124. Note that the etching process herein requires having high selectivity between the spaces 124 and the recess gate 120 to avoiding seriously affecting the spacers 124 during recessing the recessed gate 120. For example, Cl₂ can be used as a reaction gas of the plasma etching when the spacers 124 are silicon nitride, and the recessed gate 120 and the contact portions 130 between two adjacent spacers 124 are polysilicon.

According to the described etching process, a portion of the recess gate 120 between the word line 140 and the spacers 124 is removed to form a recessed portion 190. Preferably, a depth of the recessed portion 190 is substantially larger than 0.1 the width of the word line 140. In addition, the contact portions 130 between two adjacent spacers 124 are also recessed.

Referring to FIG. 3G, word line spacers 129 (also called conductive line spacers), such as silicon nitride or silicon oxynitride, are formed on sidewalls of the word lines 140 and/or the gate cap layers 142 by deposition and etching. Note that the word line spacers 129 fill the recess portion 190 of the recess gate 120 between the spacers 124 and the word line 140 on the recess gate 120. Thus, the word line spaces 129 extends downward into the recess gate 120 to provide good isolation between the recess gate 120 and the source/drain electrode 130, and eliminate leakage current or short between the contact portions 130 and the recessed gate 120.

Referring to FIG. 3H, an interlayer dielectric layer 146 is blanketly deposited overlying the substrate 100. The interlayer dielectric layer 146 can be BPSG, silicon oxide or low k dielectric materials, such as fluoride-doped silicate glass (FSG), Black Diamond (a product of Applied Materials of Santa Clara, Calif.) or other materials. Referring to FIG. 3I, the interlayer dielectric layer 146 is patterned by lithography and etching to form a bit line contact opening 148, exposing the source or drain electrode 130 (also referred to as a contact portion).

Referring to FIG. 3J, a conductive material, such as cupper, tungsten or aluminum is blanketly deposited on the interlayer dielectric layer 146 and in the bit line contact opening 148 to form bit lines 150 and a bit line contact plugs 152.

Note that a detailed description of the process conduction and material composition can take U.S. application Ser. No. 11-145-728 as a reference.

According to the described embodiments, the word lines 140 occupy smaller spacer, thus, the process window of the bit line contacts 152 is enlarged. In addition, RC delay time and capacitance between word lines 140 and bit lines 150 are reduced. Furthermore, isolation between the recess gate 120 and the source and drain electrodes 130 is improved to eliminate shorts or leakage.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a semiconductor device, comprising:
providing a substrate, comprising a recessed gate, wherein a protrusion of the recessed gate protrudes from a surface of the substrate;
forming a spacer on a sidewall of the protrusion of the recessed gate;
forming a conductive structure overlying the recessed gate, wherein the conductive structure is narrower than the recessed gate to expose a portion of the recessed gate;
utilizing an etching process to recess an exposed portion of the recessed gate, and form a recess portion between the recessed gate and the spacer; and
forming a conductive line spacer on a sidewall of the conductive line structure, wherein the conductive line spacer fills the recessed portion.

2. The method as claims in claim 1, wherein an upper portion of each spacer is narrower than a lower portion of the spacer.

3. The method as claimed in claim 1, wherein a depth of the recessed portion is substantially larger than 0.1 the width of the conductive structure.

4. The method as claimed in claim 1, wherein width of the recessed gate is substantially 1.1˜1.3 times a critical dimension of the semiconductor device.

5. The method as claimed in claim 1, wherein the conductive line spacer comprises silicon nitride.

6. The method as claimed in claim 1, wherein the recessed gate comprises doped polysilicon.

7. The method as claimed in claim 1, wherein the conductive structure comprises metal silicide.

8. The method as claimed in claim 1, wherein width of the conductive structure is substantially 0.6˜0.8 times the recessed gate.

9. The method as claimed in claim 1, further comprises:
forming an interlayer dielectric layer, at least covering the conductive structure;
patterning the interlayer dielectric layer to form an opening; and
blanketly depositing a conductive material on the interlayer and filling the opening to form a bit line and a bit line contact plug.

10. A semiconductor device, comprising:
a substrate;
a recessed gate disposed in the substrate, wherein a protrusion of the recessed gate protrudes a surface of the substrate;
a spacer disposed overlying a sidewall of the protrusion of the recessed gate;
a word line disposed overlying the recessed gate, wherein the word line is narrower than the recessed gate; and
a word line spacer disposed on a sidewall of the word line and extending downward into the recessed gate.

11. The semiconductor device as claimed in claim 10, wherein an upper portion of each spacer is narrower than a lower portion of the spacer.

12. The semiconductor device as claimed in claim 10, wherein the word line spacer comprises silicon nitride.

13. The semiconductor device as claimed in claim 10, wherein the width of the word line is substantially 0.6˜0.8 times the width of the recessed gate.

14. The semiconductor device as claimed in claim 10, further comprising:
a plurality of deep trench capacitors disposed in the substrate and surrounding the recessed gate, wherein the top portions of the deep trench capacitors protrude from the surface of the substrate;
a contact portion adjacent to the spacer;
an interlayer dielectric layer at least covering the contact portion;
a bit line contact plug disposed in the interlayer dielectric layer, electrically connecting the contact portion; and
a bit line disposed overlying the interlayer dielectric layer and the bit line contact plug.
